(19) United States
(12) Patent Application Publication
(10) Pub. No.: US 2024/0304629 A1
(43) Pub. Date: Sep. 12, 2024

(54) SEMICONDUCTOR INTEGRATED CIRCUIT DEVICE

(71) Applicant: Socionext Inc., Kanagawa (JP)

(72) Inventor: Toshio HINO, Yokohama-shi (JP)

(21) Appl. No.: 18/668,988

(22) Filed: May 20, 2024

Related U.S. Application Data
(63) Continuation of application No. PCT/JP2022/041730, filed on Nov. 9, 2022.

(30) Foreign Application Priority Data
Nov. 29, 2021 (JP) 2021-193046

(51) Int. Cl. H01L 27/092; H01L 23/528; H01L 27/02

(52) U.S. Cl. CPC H01L 27/0928; H01L 23/5286; H01L 27/0207

(57) ABSTRACT

In a standard cell of a semiconductor integrated circuit device, a metal interconnect corresponding to an input node is connected to the gates of first and second transistors, and a metal interconnect corresponding to an output node is connected to the drains of third and fourth transistors. A metal interconnect corresponding to an intermediate node is connected to a gate interconnect corresponding to the gates of the third and fourth transistors through a gate contact. The gate contact is placed at a position overlapping the third transistor in planar view.

### CROSS-REFERENCE TO RELATED APPLICATIONS

This is a continuation of International Application No. PCT/JP2022/041730 filed on Nov. 9, 2022, which claims priority to Japanese Patent Application No. 2021-193046 filed on Nov. 29, 2021. The entire disclosures of these applications are incorporated by reference herein.

### BACKGROUND

The present disclosure relates to a semiconductor integrated circuit device provided with standard cells.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, thereby designing an LSI chip.

Also, for higher integration of a semiconductor integrated circuit, used is a technique in which a contact for connecting a gate interconnect and an upper-layer metal interconnect (gate contact) is provided at a position overlapping a transistor in planar view.

U.S. Patent Application Publication No. 2021/0210479 discloses a structure of a standard cell in which gate contacts are placed at positions overlapping transistors in planar view.

In the cited patent publication, however, while placing gate contacts at positions overlapping transistors in planar view is disclosed, no detailed examination has been made on how the gate contacts should be placed to optimize the characteristics of the standard cell.

An objective of the present disclosure is improving the characteristics of a standard cell by the style of placement of gate contacts in a semiconductor integrated circuit device.

### SUMMARY

According to the first mode of the present disclosure, a semiconductor integrated circuit device includes a standard cell, wherein the standard cell includes a first transistor of a first conductivity type and a second transistor of a second conductivity type, their gates being mutually connected and their drains mutually connected, a third transistor of the first conductivity type and a fourth transistor of the second conductivity type, their gates being mutually connected and their drains mutually connected, a first metal interconnect corresponding to an input node, connected to the gates of the first and second transistors, a second metal interconnect corresponding to an intermediate node, connecting the drains of the first and second transistors and the gates of the third and fourth transistors, and a third metal interconnect corresponding to an output node, connected to the drains of the third and fourth transistors, the first and third transistors share a source, and the source is connected to a first power supply, the second and fourth transistors share a source, and the source is connected to a second power supply, the second metal interconnect is connected to a first gate interconnect corresponding to the gates of the third and fourth transistors through a first gate contact, and the first gate contact is placed at a position overlapping the third transistor in planar view.

According to the above mode, the second metal interconnect corresponding to the intermediate node is connected to the first gate interconnect corresponding to the gates of the third and fourth transistors through the first gate contact, and the first gate contact is placed at a position overlapping the third transistor in planar view. Therefore, the supply of the signal at the intermediate node to the third transistor is hastened, and that to the fourth transistor is delayed. With this, since the operation of the third transistor can be done faster than the operation of the fourth transistor, a difference in the characteristics of the transistors can be reduced.

According to the second mode of the present disclosure, a semiconductor integrated circuit device includes a standard cell, wherein the standard cell includes a first transistor of a first conductivity type and a second transistor of a second conductivity type, their gates being mutually connected and their drains mutually connected, a third transistor of the first conductivity type and a fourth transistor of the second conductivity type, their gates being mutually connected and their drains mutually connected, a first metal interconnect corresponding to an input node, connected to the gates of the first and second transistors, a second metal interconnect corresponding to an intermediate node, connecting the drains of the first and second transistors and the gates of the third and fourth transistors, and a third metal interconnect corresponding to an output node, connected to the drains of the third and fourth transistors, the first and third transistors share a source, and the source is connected to a first power supply, the second and fourth transistors share a source, and the source is connected to a second power supply, the first metal interconnect is connected to a first gate interconnect corresponding to the gates of the first and second transistors through a first gate contact, the first gate contact is placed at a position overlapping the first transistor in planar view, the second metal interconnect is connected to a second gate interconnect corresponding to the gates of the third and fourth transistors through a second gate contact, and the second gate contact is placed at a position overlapping the fourth transistor in planar view.

According to the above mode, the first metal interconnect corresponding to the input node is connected to the first gate interconnect corresponding to the gates of the first and second transistors through the first gate contact, and the first gate contact is placed at a position overlapping the first transistor in planar view. Therefore, the supply of the input signal to the first transistor is hastened, and that to the second transistor is delayed. Also, the second metal interconnect corresponding to the intermediate node is connected to the second gate interconnect corresponding to the gates of the third and fourth transistors through the second gate contact, and the second gate contact is placed at a position overlapping the fourth transistor in planar view. Therefore, the supply of the signal at the intermediate node to the fourth transistor is hastened, and that to the third transistor is delayed. With this, since the operation of the first and fourth transistors can be done faster than the operation of the second and third transistors, one of the rise and fall transitions of the output signal can be made faster than the other transition.

According to the third mode of the present disclosure, a semiconductor integrated circuit device includes a standard cell, wherein the standard cell includes first and second transistors of a first conductivity type connected in parallel between a first power supply and an output node, third and fourth transistors of a second conductivity type connected in series between the output node and a second power supply, a first metal interconnect corresponding to a first input node, connected to gates of the first and third transistors, a second metal interconnect corresponding to a second input node, connected to gates of the second and fourth transistors, and a third metal interconnect corresponding to the output node, connected to drains of the first, second, and third transistors, the first metal interconnect is connected to a first gate interconnect corresponding to the gates of the first and third transistors through a first gate contact, the second metal interconnect is connected to a second gate interconnect corresponding to the gates of the second and fourth transistors through a second gate contact, and at least one of the first and second gate contacts is placed at a position overlapping the third or fourth transistor in planar view.

According to the above mode, the first metal interconnect corresponding to the first input node is connected to the first gate interconnect corresponding to the gates of the first and third transistors through the first gate contact, and the second metal interconnect corresponding to the second input node is connected to the second gate interconnect corresponding to the gates of the second and fourth transistors through the second gate contact. At least one of the first and second gate contacts is placed at a position overlapping the third or fourth transistor of the second conductivity type in planar view. Therefore, the supply of at least one of the first and second input signals to the transistor of the second conductivity type is hastened. With this, the transition of the output signal driven by the transistor of the second conductivity type can be hastened.

According to the fourth mode of the present disclosure, a semiconductor integrated circuit device includes a standard cell, wherein the standard cell includes first, second, and third transistors of a first conductivity type connected in parallel between a first power supply and an output node, fourth, fifth, and sixth transistors of a second conductivity type connected in series between the output node and a second power supply, a first metal interconnect corresponding to a first input node, connected to gates of the first and fourth transistors, a second metal interconnect corresponding to a second input node, connected to gates of the second and fifth transistors, a third metal interconnect corresponding to a third input node, connected to gates of the third and sixth transistors, and a fourth metal interconnect corresponding to the output node, connected to drains of the first, second, third, and fourth transistors, the first metal interconnect is connected to a first gate interconnect corresponding to the gates of the first and fourth transistors through a first gate contact, the second metal interconnect is connected to a second gate interconnect corresponding to the gates of the second and fifth transistors through a second gate contact, the third metal interconnect is connected to a third gate interconnect corresponding to the gates of the third and sixth transistors through a third gate contact, and at least one of the first, second, and third gate contacts is placed at a position overlapping the fourth, fifth, or sixth transistor in planar view.

According to the above mode, the first metal interconnect corresponding to the first input node is connected to the first gate interconnect corresponding to the gates of the first and fourth transistors through the first gate contact, the second metal interconnect corresponding to the second input node is connected to the second gate interconnect corresponding to the gates of the second and fifth transistors through the second gate contact, and the third metal interconnect corresponding to the third input node is connected to the third gate interconnect corresponding to the gates of the third and sixth transistors through the third gate contact. At least one of the first, second, and third gate contacts is placed at a position overlapping the fourth, fifth, or sixth transistor of the second conductivity type in planar view. Therefore, the supply of at least one of the first to third input signals to the transistor of the second conductivity type is hastened. With this, the transition of the output signal driven by the transistor of the second conductivity type can be hastened.

According to the present disclosure, in a semiconductor integrated circuit device, the characteristics of a standard cell can be improved by the style of placement of gate contacts.

### BRIEF DESCRIPTION OF THE DRAWINGS

FIG. 1 is a plan view showing an example of the layout structure of a standard cell constituting a semiconductor integrated circuit device according to the first embodiment.

FIG. 2 shows a cross-sectional structure of the standard cell shown in FIG. 1.

FIG. 3 is a circuit diagram of the standard cell shown in FIG. 1.

FIG. 4 is a plan view showing another example of the layout structure of the standard cell in the first embodiment.

FIGS. 5A-5B are plan views showing other examples of the layout structure of the standard cell in the first embodiment.

FIG. 6 is a plan view showing an example of the layout structure of a standard cell in Alteration 1 of the first embodiment.

FIGS. 7A-7B are plan views showing examples of the layout structure of a standard cell in Alteration 2 of the first embodiment.

FIGS. 8A-8B are plan views showing examples of the layout structure of a standard cell in Alteration 3 of the first embodiment.

FIGS. 9A-9B are plan views showing examples of the layout structure of the standard cell in Alteration 3 of the first embodiment.

FIGS. 10A-10B are plan views showing examples of the layout structure of a standard cell in Alteration 4 of the first embodiment.

FIGS. 11A-11B are plan views showing examples of the layout structure of the standard cell in Alteration 4 of the first embodiment.

FIGS. 12A-12B are plan views showing examples of the layout structure of a standard cell in Alteration 5 of the first embodiment.

FIGS. 13A-13B are plan views showing examples of the layout structure of the standard cell in Alteration 5 of the first embodiment.

FIGS. 14A-14B are plan views showing examples of the layout structure of a standard cell in Alteration 6 of the first embodiment.

FIGS. 15A-15B are plan views showing examples of the layout structure of the standard cell in Alteration 6 of the first embodiment.

FIGS. 16A-16B are circuit diagrams showing circuit structures of NAND circuits, where FIG. 16A shows a 2-input NAND circuit and FIG. 16B shows a 3-input NAND circuit.

FIGS. 17A-17C are plan views showing examples of the layout structure of a standard cell constituting a semiconductor integrated circuit device according to the second embodiment.

FIGS. 18A-18B are plan views showing other examples of the layout structure of the standard cell constituting the semiconductor integrated circuit device according to the second embodiment.

FIGS. 19A-19B are circuit diagrams showing circuit structures of NOR circuits, where FIG. 19A shows a 2-input NOR circuit and FIG. 19B shows a 3-input NOR circuit.

FIGS. 20A-20B are plan views showing examples of the layout structure of a standard cell in an alteration of the second embodiment.

FIGS. 21A-21B are plan views showing other examples of the layout structure of the standard cell in the alteration of the second embodiment.

### DETAILED DESCRIPTION

Embodiments of the present disclosure will be described hereinafter with reference to the accompanying drawings. In the following embodiments, a semiconductor integrated circuit device includes a plurality of standard cells (herein simply referred to as cells appropriately), and at least some of the plurality of standard cells include nanosheet transistors.

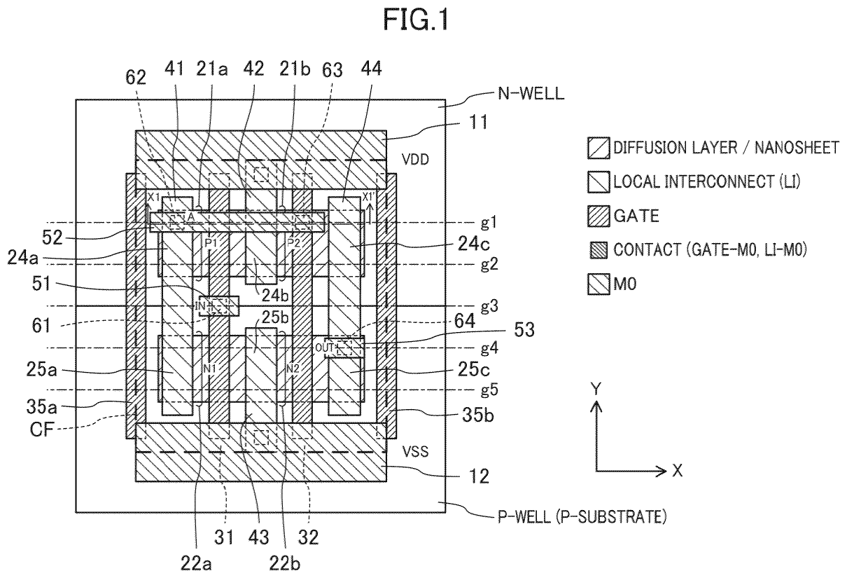

In the present disclosure, “VDD” and “VSS” indicate power supply voltages or power supplies themselves. Also, “IN”, “A”, and “OUT” represent nodes or signals. Note also that, in the plan views such as FIG. 1, the horizontal direction in the figure is called an X direction (corresponding to the first direction), the vertical direction in the figure is called a Y direction (corresponding to the second direction), and the direction perpendicular to the substrate plate is called a Z direction.

### First Embodiment

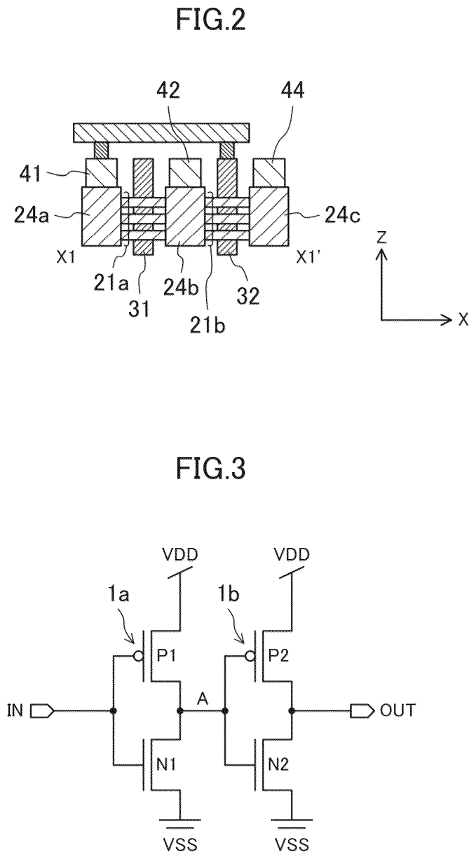

FIG. 1 is a plan view showing an example of the layout structure of a standard cell constituting a semiconductor integrated circuit device according to the first embodiment. FIG. 2 is a view showing a cross-sectional structure of the standard cell shown in FIG. 1, which is a cross-sectional view taken along line X1-X1′ in FIG. 1.

FIG. 3 is a circuit diagram of the standard cell shown in FIG. 1. The standard cell in this embodiment implements a buffer circuit. As shown in FIG. 3, the buffer circuit includes an input node IN, a first inverter 1a having a p-type transistor P1 and an n-type transistor N1, an intermediate node A, a second inverter 1b having a p-type transistor P2 and an n-type transistor N2, and an output node OUT.

The drains, and the gates, of the transistors P1 and N1 are mutually connected, and the drains, and the gates, of the transistors P2 and N2 are mutually connected. The sources of the transistors P1 and P2 are connected to VDD, and the sources of the transistors N1 and N2 are connected to VSS. The input node IN is connected to the gates of the transistors P1 and N1. The drains of the transistors P1 and N1 are connected to the gates of the transistors P2 and N2 through the intermediate node A. The drains of the transistors P2 and N2 are connected to the output node OUT.

The layout structure of the standard cell shown in FIGS. 1 and 2 will be described hereinafter. In FIG. 1, the cell boundaries of the standard cell are illustrated as a cell frame CF. The standard cell in FIG. 1 and other standard cells are arranged in line in the X direction with the cell frames CF of adjacent cells touching each other, to form a cell row. A plurality of such cell rows are arranged in the Y direction with the cell frames CF of adjacent cell rows touching each other. Note however that such a plurality of cell rows are inverted vertically every other row.

As shown in FIG. 1, power supply lines 11 and 12 extending in the X direction are provided on both ends of the standard cell in the Y direction. Both the power supply lines 11 and 12 are M0 interconnects (M0 is a metal interconnect layer). The power supply line 11 supplies the power supply voltage VDD, and the power supply line 12 supplies the power supply voltage VSS. The power supply lines 11 and 12 are each shared by other cells arranged in line in the X direction, constituting a power supply line placed between adjacent cell rows.

The p-type transistors P1 and P2 are formed on an N-well, and the n-type transistors N1 and N2 are formed on a P-well or a p-type substrate. The transistors P1 and N1 are arranged side by side in the Y direction. The transistors P2 and N2 are adjacent to the transistors P1 and N1 in the X direction, and arranged side by side in the Y direction.

The transistors P1, P2, N1, and N2 have, as channel portions, nanosheets 21a, 21b, 22a, and 22b, respectively, each made of three sheets. That is, the transistors P1, P2, N1, and N2 are nanosheet FETs. Note that the number of nanosheets of each nanosheet FET is not limited to three. The regions of the nanosheets 21a, 21b, 22a, and 22b each define the channel regions of the transistors P1, P2, N1, and N2.

Pads 24a, 24b, and 24c, each made of a semiconductor layer of an integral structure connected to the three sheets, are respectively formed on the left side of the nanosheets 21a in the figure, between the nanosheets 21a and 21b, and on the right side of the nanosheets 21b in the figure. The pad 24a is to be the drain region of the transistor P1, the pad 24b is to be the source regions of the transistors P1 and P2, and the pad 24c is to be the drain region of the transistor P2.

Pads 25a, 25b, and 25c, each made of a semiconductor layer of an integral structure connected to the three sheets, are respectively formed on the left side of the nanosheets 22a in the figure, between the nanosheets 22a and 22b, and on the right side of the nanosheets 22b in the figure. The pad 25a is to be the drain region of the transistor N1, the pad 25b is to be the source regions of the transistors N1 and N2, and the pad 25c is to be the drain region of the transistor N2.

Gate interconnects 31 and 32 extending in parallel in the Y direction are formed. The gate interconnect 31 surrounds the peripheries of the nanosheets 21a of the transistor P1 and the nanosheets 22a of the transistor N1 in the Y direction and the Z direction via a gate insulating film (not shown). The gate interconnect 31 corresponds to the gates of the transistors P1 and N1. The gate interconnect 32 surrounds the peripheries of the nanosheets 21b of the transistor P2 and the nanosheets 22b of the transistor N2 in the Y direction and the Z direction via a gate insulating film (not shown). The gate interconnect 32 corresponds to the gates of the transistors P2 and N2. Also, dummy gate interconnects 35a and 35b are formed over the cell frame CF on the outer sides of the gate interconnects 31 and 32 in the X direction.

In a local interconnect layer, local interconnects 41, 42, 43, and 44 extending in the Y direction are formed. The local interconnect 41 is connected to the pads 24a and 25b. The local interconnect 42 is connected to the pad 24b and also connected to the power supply line 11 through a via. The local interconnect 43 is connected to the pad 25b and also connected to the power supply line 12 through a via. The local interconnect 44 is connected to the pads 24c and 25c.

Lines g1, g2, g3, g4, and g5 are virtual grid lines for defining the positions of M0 interconnects. The grid lines g1 to g5 extend in the X direction and are spaced equally in the Y direction. The grid lines g1 and g2 are positioned to overlap the p-type transistors in planar view, and the grid lines g4 and g5 are positioned to overlap the n-type transistors in planar view. The grid line g3 does not overlap any transistors in planar view. M0 interconnects, contacts connecting the gate interconnects and the M0 interconnects (gate contacts), and contacts connecting the local interconnects and the M0 interconnects to be described later are placed on the grid lines g1 to g5.

In planar view, the position of the grid line g1 is closer to the power supply line 11 than the center of the channel regions of the transistors P1 and P2 in the Y direction, and the position of the grid line g2 is farther from the power supply line 11 than the center of the channel regions of the transistors P1 and P2 in the Y direction. In planar view, the position of the grid line g5 is closer to the power supply line 12 than the center of the channel regions of the transistors N1 and N2 in the Y direction, and the position of the grid line g4 is farther from the power supply line 12 than the center of the channel regions of the transistors N1 and N2 in the Y direction.

In the M0 interconnect layer, metal interconnects 51, 52, and 53 extending in the X direction are formed. The metal interconnect 51, corresponding to the input node IN, is connected to the gate interconnect 31 through a gate contact 61. The metal interconnect 52, corresponding to the intermediate node A, is connected to the local interconnect 41 through a contact 62, and also connected to the gate interconnect 32 through a gate contact 63. The metal interconnect 53, corresponding to the output node OUT, is connected to the local interconnect 44 through a contact 64.

In the layout of FIG. 1, the metal interconnect 51 corresponding to the input node IN and the gate contact 61 are placed on the grid line g3. The metal interconnect 52 corresponding to the intermediate node A, the contact 62, and the gate contact 63 are placed on the grid line g1. The metal interconnect 53 corresponding to the output node OUT and the contact 64 are placed on the grid line g4.

The relationship between the gate contacts and the positions of the grid lines g1 to g5 will be described hereinafter.

When a gate contact for the gate interconnect 31, 32 is placed on the grid line g1, g2, the position of the gate contact is closer to a p-type transistor and farther from an n-type transistor. Therefore, due to gate interconnect resistance, signal supply to the p-type transistor is hastened and signal supply to the n-type transistor is delayed. Also, since the grid line g1 is farther from the n-type transistor than the grid line g2, the above effect is exhibited more significantly by placing the gate contact on the grid line g1.

Likewise, when a gate contact for the gate interconnect 31, 32 is placed on the grid line g4, g5, the position of the gate contact is closer to an n-type transistor and farther from a p-type transistor. Therefore, due to gate interconnect resistance, signal supply to the n-type transistor is hastened and signal supply to the p-type transistor is delayed. Also, since the grid line g5 is farther from the p-type transistor than the grid line g4, the above effect is exhibited more significantly by placing the gate contact on the grid line g5.

By determining the position of the gate contact taking the above effect into consideration, it becomes possible to lessen a difference, if any, in characteristics between the p-type transistor and the n-type transistor, or to hasten either the rise or fall of the output signal, for example.

For example, in the layout of FIG. 1, the gate contact 63 connecting the metal interconnect 52 corresponding to the intermediate node A and the gate interconnect 32 is placed on the grid line g1. That is, the gate contact 63 is at a position on the p-type transistor part of the gate interconnect 32. Therefore, the signal at the intermediate node A is supplied earlier to the p-type transistor P2 than to the n-type transistor N2. With this, since the operation of the p-type transistor P2 can be done faster than that of the n-type transistor N2, the following effects can be obtained, for example.

1) When the operating speed of the p-type transistor is slower than that of the n-type transistor, the difference in speed between the rise and fall of the output of the buffer circuit can be reduced.

2) When the operating speeds of the p-type transistor and the n-type transistor are the same, the rise of the output can be made faster than the fall.

Note that, in the layout of FIG. 1, while the M0 interconnect 53 corresponding to the output node OUT and the contact 64 are placed on the grid line g4, they may be placed on another grid line.

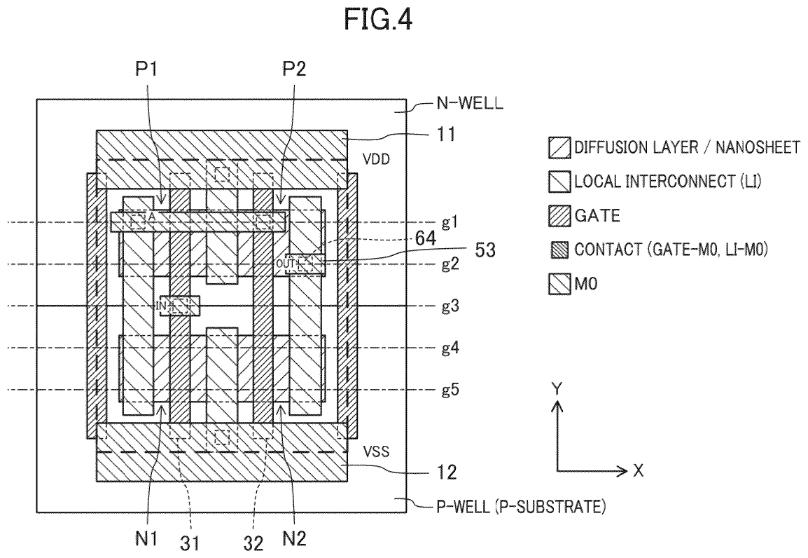

In a layout of FIG. 4, compared with the layout of FIG. 1, the position of the M0 interconnect 53 corresponding to the output node OUT and the contact 64 is changed to a position on the grid line g2. As shown in FIG. 4, since the resistance value from the p-type transistor P2 to the output node OUT can be reduced by placing the output node OUT on the p-type transistor part, the above effects 1) and 2) can be further enhanced.

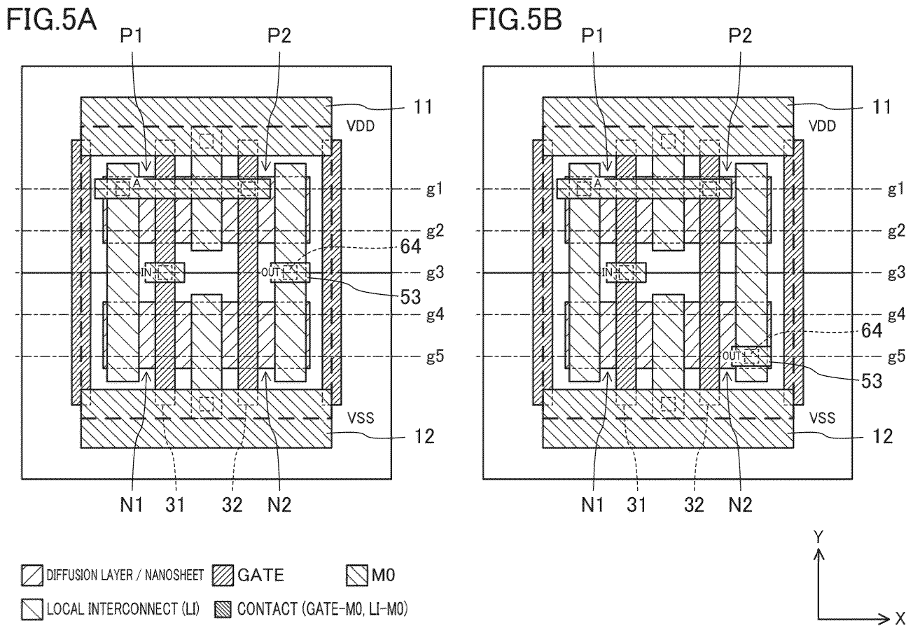

Note that, as shown in layouts of FIGS. 5A and 5B, the M0 interconnect 53 corresponding to the output node OUT and the contact 64 may be placed at another position. In FIG. 5A, the M0 interconnect 53 and the contact 64 are placed on the grid line g3. In FIG. 5B, the M0 interconnect 53 and the contact 64 are placed on the grid line g5.

### Alteration 1

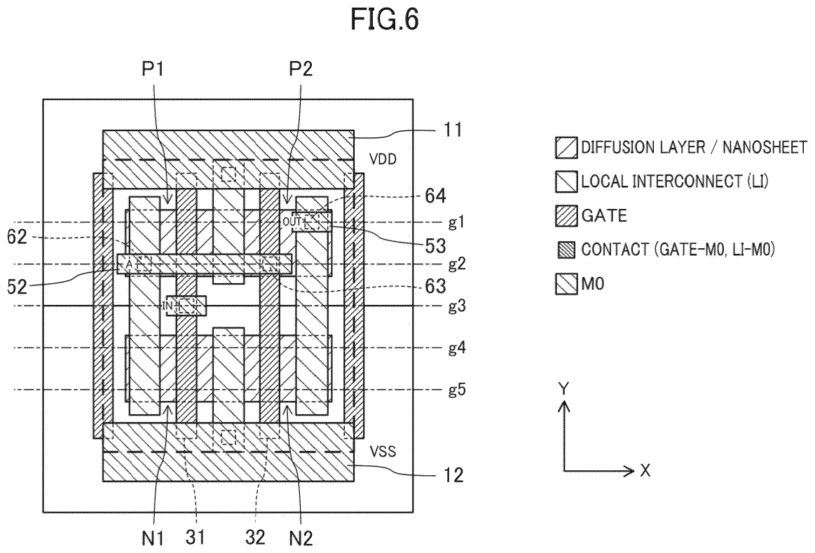

In a layout of FIG. 6, the gate contact 63 connecting the metal interconnect 52 corresponding to the intermediate node A and the gate interconnect 32 are placed on the grid line g2. Therefore, since the signal at the intermediate node A is supplied earlier to the p-type transistor P2 than to the n-type transistor N2, the operation of the p-type transistor P2 can be done faster than the operation of the n-type transistor N2, whereby the above effects 1) and 2) can be obtained. Also, in the layout of FIG. 6, compared with the layout of FIG. 1, since the metal interconnect 52 is farther from the power supply line 11, it is less influenced by reduction in signal speed due to an capacitance between itself and the power supply line 11.

Also, in the layout of FIG. 6, the M0 interconnect 53 corresponding to the output node OUT and the contact 64 are placed on the grid line g1. Therefore, since the resistance value from the p-type transistor P2 to the output node OUT can be reduced, the above effects 1) and 2) can be further enhanced. Note that the M0 interconnect 53 corresponding to the output node OUT and the contact 64 may be placed on another grid line.

### Alteration 2

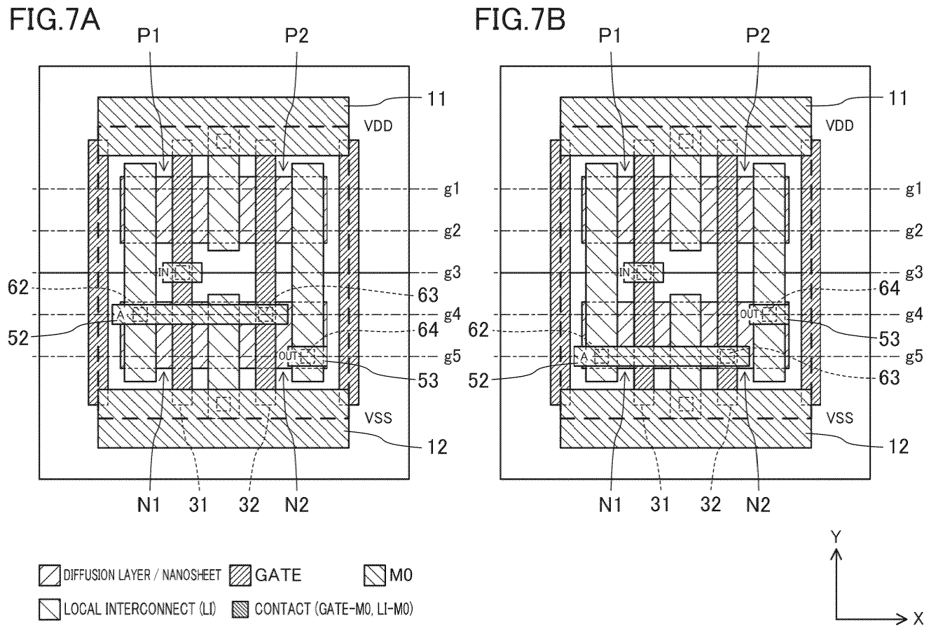

In a layout of FIG. 7A, the gate contact 63 is placed on the grid line g4. In a layout of FIG. 7B, the gate contact 63 is placed on the grid line g5. That is, the gate contact 63 is at a position on the n-type transistor part of the gate interconnect 32. Therefore, the signal at the intermediate node A is supplied earlier to the n-type transistor N2 than to the p-type transistor P2. With this, since the operation of the n-type transistor N2 can be done faster than the operation of the p-type transistor P2, the following effects can be obtained, for example.
1) When the operating speed of the n-type transistor is slower than that of the p-type transistor, the difference in speed between the rise and fall of the output of the buffer circuit can be reduced.
2) When the operating speeds of the p-type transistor and the n-type transistor are the same, the fall of the output can be made faster than the rise.

Also, in the layout of FIG. 7A, the M0 interconnect 53 corresponding to the output node OUT and the contact 64 are placed on the grid line g5. In the layout of FIG. 7B, the M0 interconnect 53 and the contact 64 are placed on the grid line g4. Therefore, since the resistance value from the n-type transistor N2 to the output node OUT can be reduced, the above effects 1) and 2) can be further enhanced. Note that the M0 interconnect 53 and the contact 64 may be placed on another grid line.

### Alteration 3

The gate contact 61 connecting the metal interconnect 51 corresponding to the input node IN and the gate interconnect 31 may be placed on the p-type transistor part. In this case, the input signal IN is supplied earlier to the p-type transistor P1 than to the n-type transistor N1. With this, since the operation of the p-type transistor P1 can be done faster than the operation of the n-type transistor N1, the following effects can be obtained, for example.
1) When the operating speed of the p-type transistor is slower than that of the n-type transistor, the difference in speed between the rise and fall of the intermediate signal of the buffer circuit can be reduced.
2) When the operating speeds of the p-type transistor and the n-type transistor are the same, the rise of the intermediate signal can be made faster than the fall.

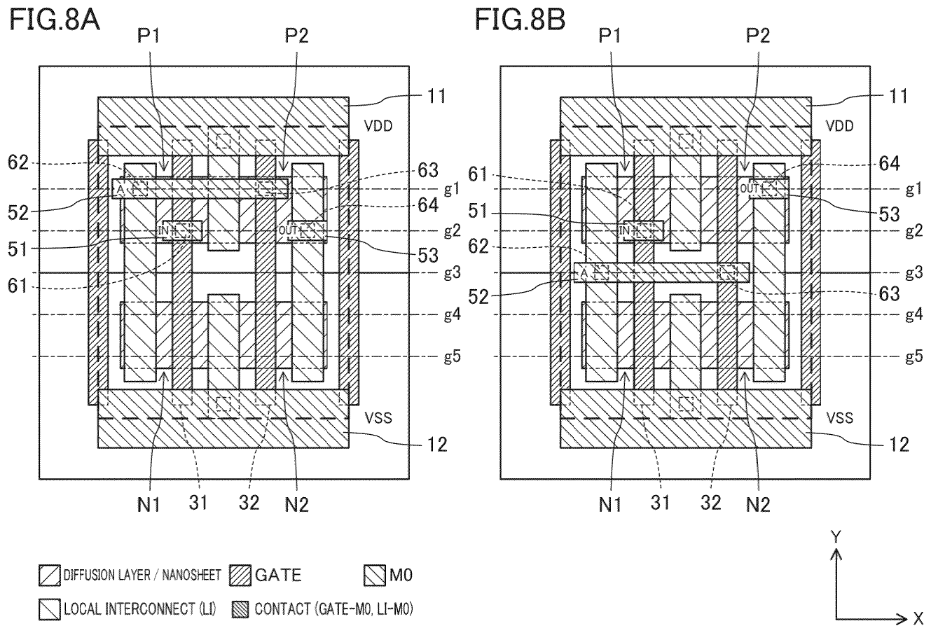

In layouts of FIGS. 8A and 8B, the gate contact 61 is placed on the grid line g2. In addition, in the layout of FIG. 8A, the gate contact 63 is placed on the grid line g1. Therefore, the signal at the intermediate node A is supplied earlier to the p-type transistor P2 than to the n-type transistor N2. With this, the operation of the p-type transistor P2 can be done faster than the operation of the n-type transistor N2. Note that, as in the layout of FIG. 8B, the gate contact 63 may be placed on the grid line g3.

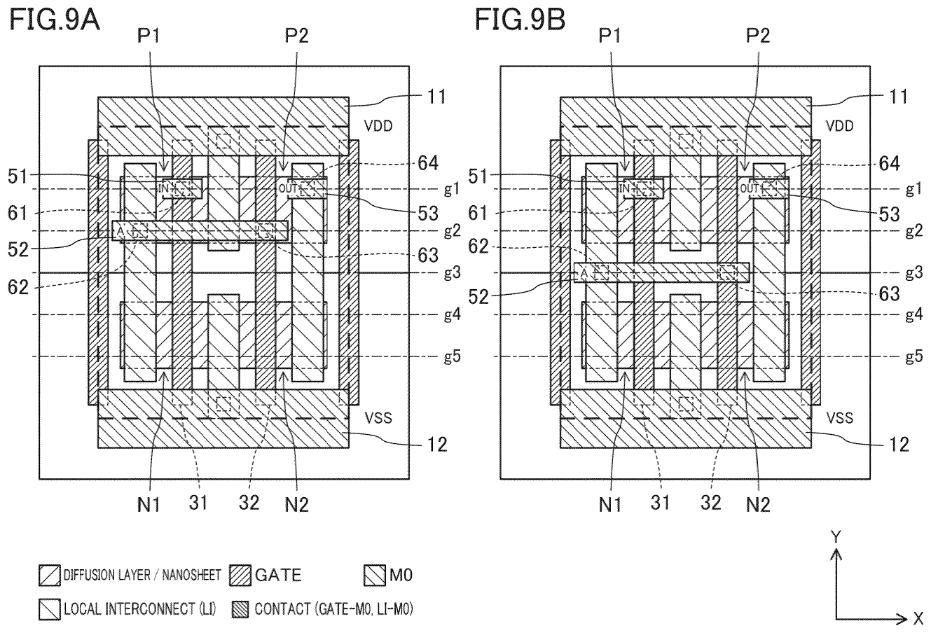

In layouts of FIGS. 9A and 9B, the gate contact 61 is placed on the grid line g1. In addition, in the layout of FIG. 9A, the gate contact 63 is placed on the grid line g2. Therefore, the signal at the intermediate node A is supplied earlier to the p-type transistor P2 than to the n-type transistor N2. With this, the operation of the p-type transistor P2 can be done faster than the operation of the n-type transistor N2. Note that, as in the layout of FIG. 9B, the gate contact 63 may be placed on the grid line g3.

Also, in the layouts of FIGS. 8A-8B and 9A-9B, the M0 interconnect 53 corresponding to the output node OUT and the contact 64 are placed on the p-type transistor part. Specifically, in the layout of FIG. 8A, the M0 interconnect 53 and the contact 64 are placed on the grid line g2. In the layouts of FIGS. 8B, 9A, and 9B, the M0 interconnect 53 and the contact 64 are placed on the grid line g1. Therefore, the resistance value from the p-type transistor P2 to the output node OUT can be reduced. Note that, in the layouts of FIGS. 8A-8B and 9A-9B, the M0 interconnect 53 and the contact 64 may be placed on another grid line.

### Alteration 4

The metal interconnect 51 corresponding to the input node IN and the gate contact 61 may be placed on the n-type transistor part. In this case, the input signal IN is supplied earlier to the n-type transistor N1 than to the p-type transistor P1. With this, since the operation of the n-type transistor N1 can be done faster than the operation of the p-type transistor P1, the following effects can be obtained, for example.
1) When the operating speed of the n-type transistor is slower than that of the p-type transistor, the difference in speed between the rise and fall of the intermediate signal of the buffer circuit can be reduced.
2) When the operating speeds of the n-type transistor and the p-type transistor are the same, the fall of the intermediate signal can be made faster than the rise.

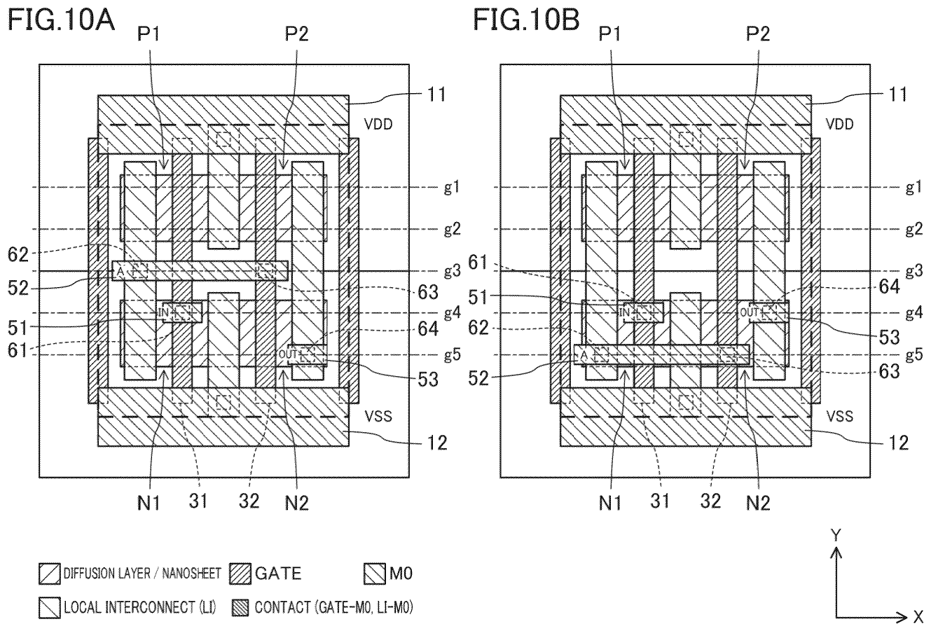

In layouts of FIGS. 10A and 10B, the metal interconnect 51 corresponding to the input node IN and the gate contact 61 are placed on the grid line g4. In addition, in the layout of FIG. 10B, the metal interconnect 52 corresponding to the intermediate node A and the gate contact 63 are placed on the grid line g5. Therefore, the signal at the intermediate node A is supplied earlier to the n-type transistor N2 than to the p-type transistor P2. With this, the operation of the n-type transistor N2 can be done faster than the operation of the p-type transistor P2. Note that, as in the layout of FIG. 10A, the gate contact 63 may be placed on the grid line g3.

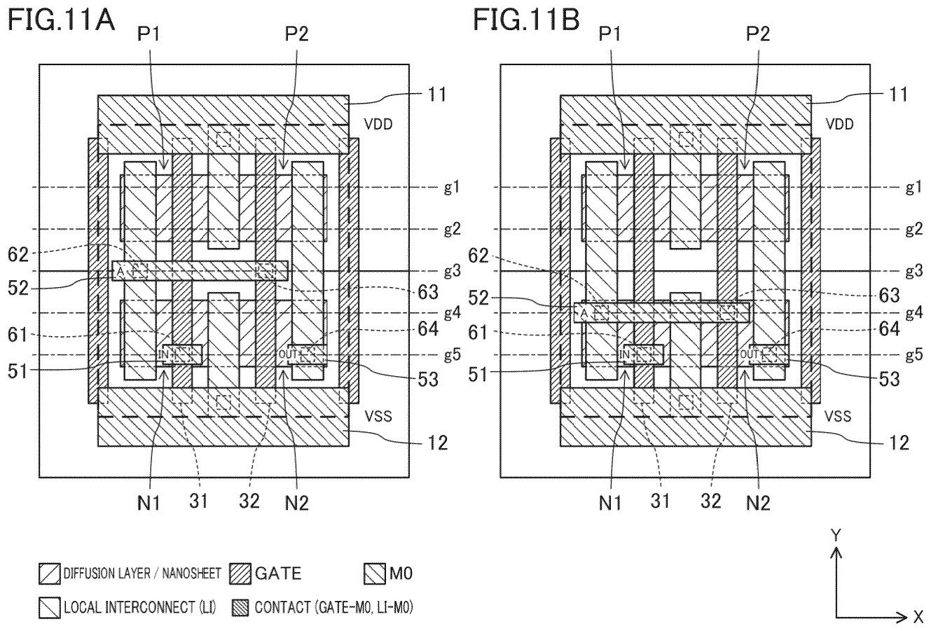

In layouts of FIGS. 11A and 11B, the gate contact 61 is placed on the grid line g5. In addition, in the layout of FIG. 11B, the gate contact 63 is placed on the grid line g4. Therefore, the signal at the intermediate node A is supplied earlier to the n-type transistor N2 than to the p-type transistor P2. With this, the operation of the n-type transistor N2 can be done faster than the operation of the p-type transistor P2. Note that, as in the layout of FIG. 11A, the gate contact 63 may be placed on the grid line g3.

Also, in the layouts of FIGS. 10A-10B and 11A-11B, the M0 interconnect 53 corresponding to the output node OUT and the contact 64 are placed on the n-type transistor part. Specifically, in the layouts of FIGS. 10A, 11A, and 11B, the M0 interconnect 53 and the contact 64 are placed on the grid line g5. In the layout of FIG. 10B, the M0 interconnect 53 and the contact 64 are placed on the grid line g4. Therefore, the resistance value from the n-type transistor N2 to the output node OUT can be reduced. Note that, in the layouts of FIGS. 10A-10B and 11A-11B, the M0 interconnect 53 and the contact 64 may be placed on another grid line.

### Alteration 5

While the metal interconnect 51 corresponding to the input node IN and the gate contact 61 are placed on the p-type transistor part, the metal interconnect 52 corresponding to the intermediate node A and the gate contact 63 may be placed on the n-type transistor part. With this, since the operation of the p-type transistor P1 can be done faster than the operation of the n-type transistor N1, the rise of the intermediate signal A can be made faster than the fall. In addition, since the operation of the n-type transistor N2 can be done faster than the operation of the p-type transistor P2, the fall of the output signal OUT can be made faster than the rise. Therefore, in the buffer circuit as a whole, the rise of the output signal OUT can be made slower than the fall.

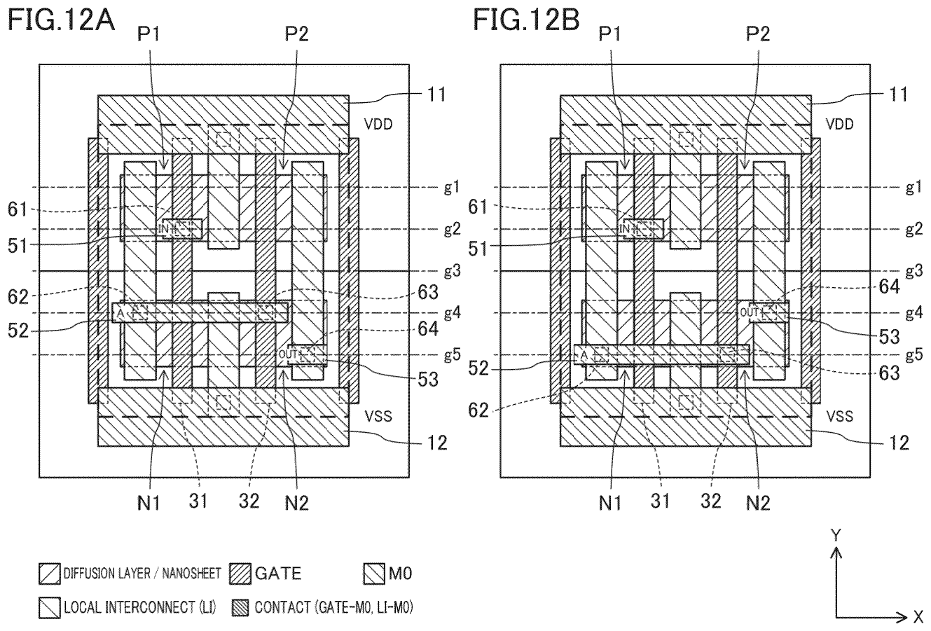

In layouts of FIGS. 12A and 12B, the gate contact 61 is placed on the grid line g2. In addition, in the layout of FIG. 12A, the gate contact 63 is placed on the grid line g4, and so the rise of the output signal OUT can be delayed as described above. In the layout of FIG. 12B, the gate contact 63 is placed on the grid line g5, and so the rise of the output signal OUT can be further delayed.

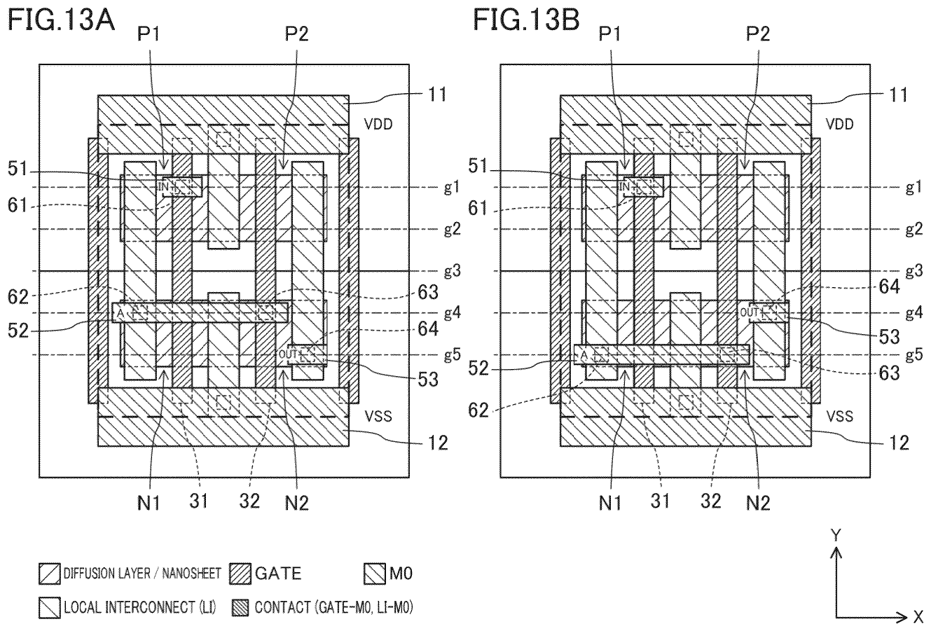

In layouts of FIGS. 13A and 13B, the gate contact 61 is placed on the grid line g1. In addition, in the layout of FIG. 13A, the gate contact 63 is placed on the grid line g4, and so the rise of the output signal OUT can be delayed as described above. In the layout of FIG. 13B, the gate contact 63 is placed on the grid line g5, and so the rise of the output signal OUT can be further delayed. Moreover, in the layouts of FIGS. 13A and 13B, compared with FIGS. 12A and 12B, since the metal interconnect 51 corresponding to the input node IN and the gate contact 61 are farther from the n-type transistor N1, the rise of the output signal OUT can be furthermore delayed.

Also, in the layouts of FIGS. 12A-12B and 13A-13B, the M0 interconnect 53 corresponding to the output node OUT and the contact 64 are placed on the n-type transistor part. Specifically, in the layouts of FIGS. 12A and 13A, the M0 interconnect 53 and the contact 64 are placed on the grid line g5. In the layouts of FIGS. 12B and 13B, the M0 interconnect 53 and the contact 64 are placed on the grid line g4. Therefore, the resistance value from the n-type transistor N2 to the output node OUT can be reduced. Note that, in the layouts of FIGS. 12A-12B and 13A-13B, the M0 interconnect 53 and the contact 64 may be placed on another grid line.

### Alteration 6

In contrast to Alteration 5, while the metal interconnect 51 corresponding to the input node IN and the gate contact 61 are placed on the n-type transistor part, the metal interconnect 52 corresponding to the intermediate node A and the gate contact 63 may be placed on the p-type transistor part. With this, since the operation of the n-type transistor N1 can be done faster than the operation of the p-type transistor P1, the fall of the intermediate signal A can be made faster than the rise. Also, since the operation of the p-type transistor P2 can be done faster than the operation of the n-type transistor N2, the rise of the output signal OUT can be made faster than the fall. Therefore, in the buffer circuit as a whole, the fall of the output signal OUT can be made slower than the rise.

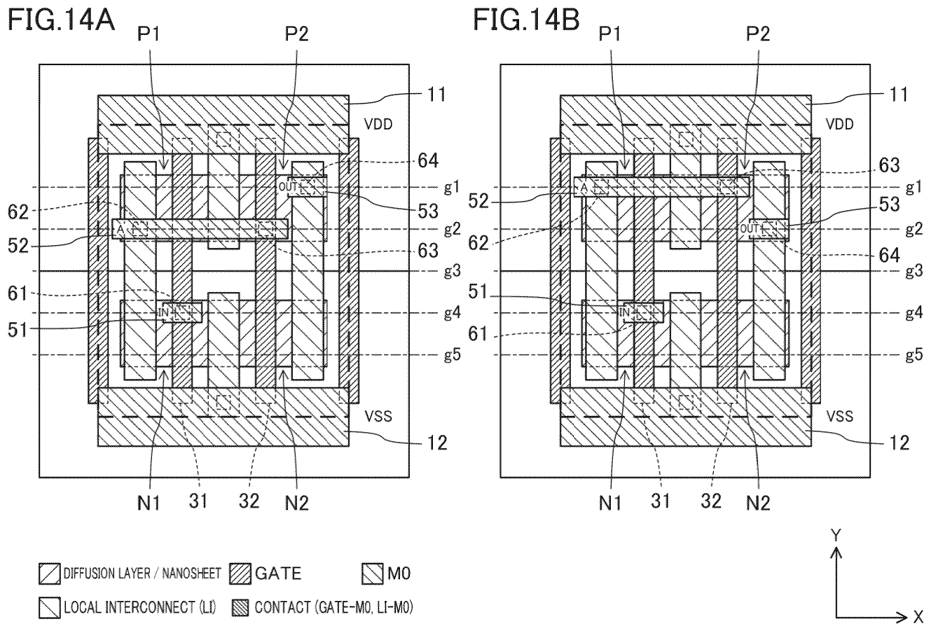

In layouts of FIGS. 14A and 14B, the gate contact 61 is placed on the grid line g4. In addition, in the layout of FIG. 14A, the gate contact 63 is placed on the grid line g2, and so the fall of the output signal OUT can be delayed as described above. In the layout of FIG. 14B, the gate contact 63 is placed on the grid line g1, and so the fall of the output signal OUT can be further delayed.

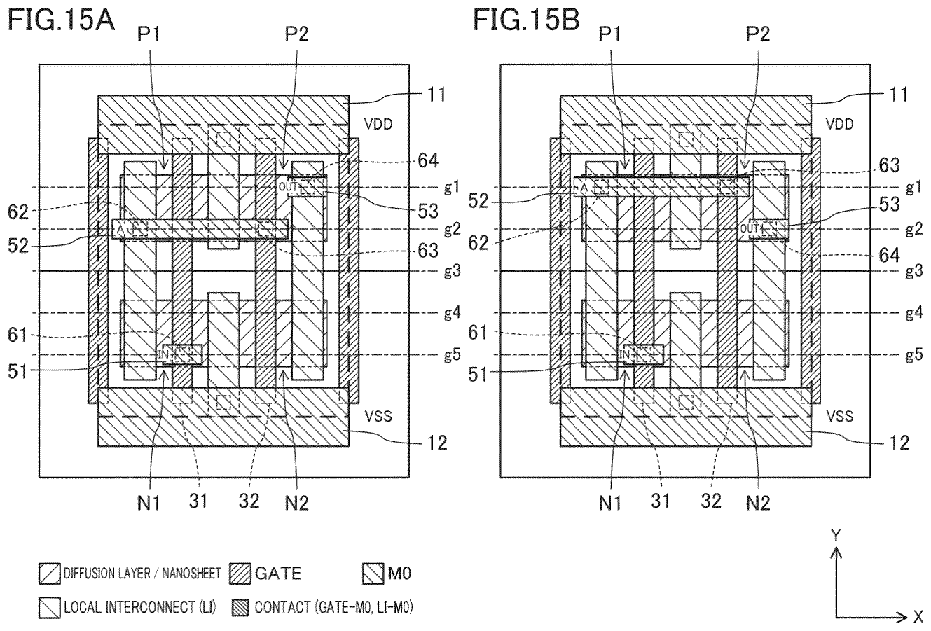

In layouts of FIGS. 15A and 15B, the gate contact 61 is placed on the grid line g5. In addition, in the layout of FIG. 15A, the gate contact 63 is placed on the grid line g2. Therefore, the fall of the output signal OUT can be delayed as described above. In the layout of FIG. 15B, the gate contact 63 is placed on the grid line g1, and so the fall of the output signal OUT can be further delayed. Moreover, in the layouts of FIGS. 15A and 15B, compared with FIGS. 14A and 14B, since the metal interconnect 51 corresponding to the input node IN and the gate contact 61 are farther from the p-type transistor P1, the fall of the output signal OUT can be furthermore delayed.

Also, in the layouts of FIGS. 14A-14B and 15A-15B, the M0 interconnect 53 corresponding to the output node OUT and the contact 64 are placed on the p-type transistor part. Specifically, in the layouts of FIGS. 14A and 15A, the M0 interconnect 53 and the contact 64 are placed on the grid line g1. In the layouts of FIGS. 14B and 15B, the M0 interconnect 53 and the contact 64 are placed on the grid line g2. Therefore, the resistance value from the p-type transistor P2 to the output node OUT can be reduced. Note that, in the layouts of FIGS. 14A-14B and 15A-15B, the M0 interconnect 53 and the contact 64 may be placed on another grid line.

### Second Embodiment

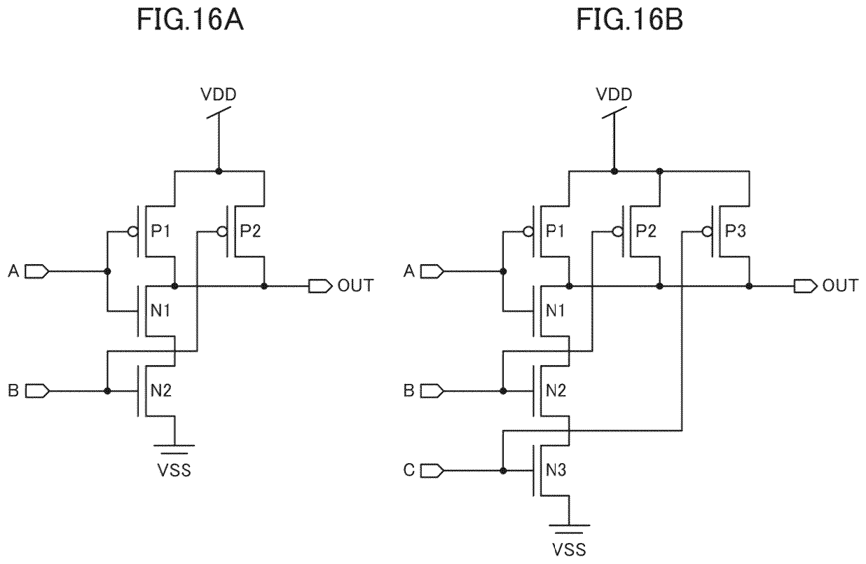

FIGS. 16A-16B are circuit diagrams showing circuit structures of NAND circuits, where FIG. 16A shows a 2-input NAND circuit and FIG. 16B shows a 3-input NAND circuit. As shown in FIG. 16A, in the 2-input NAND circuit, p-type transistors P1 and P2 are connected in parallel between VDD and an output node OUT, and n-type transistors N1 and N2 are connected in series between the output node OUT and VSS. An input node A is connected to the gates of the p-type transistor P1 and the n-type transistor N1. An input node B is connected to the gates of the p-type transistor P2 and the n-type transistor N2.

As shown in FIG. 16B, in the 3-input NAND circuit, p-type transistors P1, P2, and P3 are connected in parallel between VDD and an output node OUT, and n-type transistors N1, N2, and N3 are connected in series between the output node OUT and VSS. An input node A is connected to the gates of the p-type transistor P1 and the n-type transistor N1. An input node B is connected to the gates of the p-type transistor P2 and the n-type transistor N2. An input node C is connected to the gates of the p-type transistor P3 and the n-type transistor N3.

As shown in FIGS. 16A-16B, in the 2-input NAND circuit and the 3-input NAND circuit, the n-type transistors are connected in series between the output node OUT and VSS. Therefore, assuming that the drive capabilities of the p-type transistors and the n-type transistors are the same, the fall of the output signal OUT will be slower than the rise thereof due to the serial connection of the n-type transistors.

In consideration of the above, in this embodiment, in layouts of standard cells implementing the 2-input NAND circuit and the 3-input NAND circuit, gate contacts for supplying input signals to the gates of the p-type transistors and the n-type transistors are placed on the n-type transistor part. Since this hastens signal supply to the n-type transistors while delaying signal supply to the p-type transistors, the fall of the output signal OUT can be hastened.

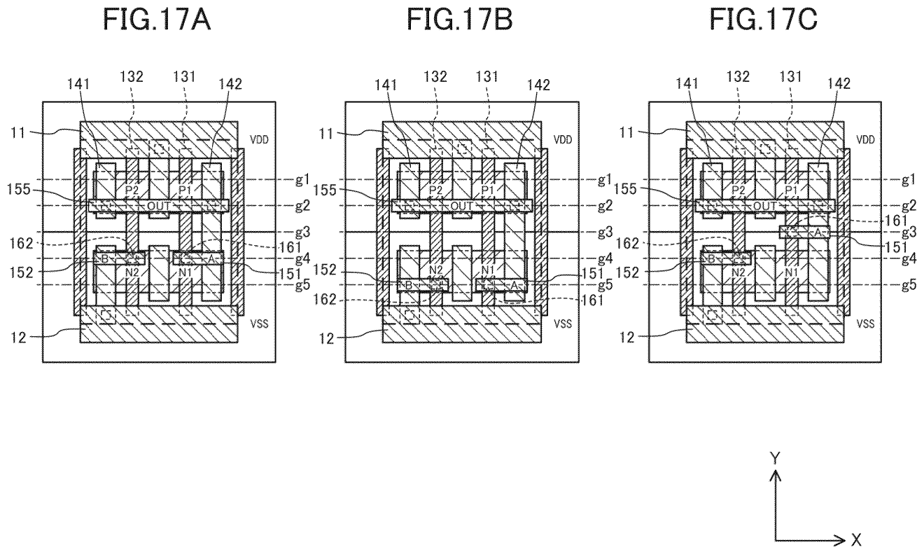

FIGS. 17A-17C are plan views showing layout examples of standard cells implementing 2-input NAND circuits. Note that, in this embodiment, description may be omitted for configurations easily known by analogy from the description in the first embodiment. A gate interconnect 131 corresponds to the gates of the transistors P1 and N1, and a gate interconnect 132 corresponds to the gates of the transistors P2 and N2. A metal interconnect 151 corresponding to the input node A is connected to the gate interconnect 131 through a gate contact 161. A metal interconnect 152 corresponding to the input node B is connected to the gate interconnect 132 through a gate contact 162. A metal interconnect 155 corresponding to the output node OUT is connected to a local interconnect 141 corresponding to the drain of the transistor P2 and to a local interconnect 142 corresponding to the drains of the transistors P1 and N1 through contacts.

In the layout of FIG. 17A, the gate contact 161 connecting the metal interconnect 151 corresponding to the input node A and the gate interconnect 131 is placed on the grid line g4. Also, the gate contact 162 connecting the metal interconnect 152 corresponding to the input node B and the gate interconnect 132 is placed on the grid line g4. That is, since the gate contacts for supplying the input signals A and B are on the n-type transistor part, signal supply to the n-type transistors is hastened and signal supply to the p-type transistors is delayed. With this, the fall of the output signal OUT can be hastened. For example, assuming that the drive capabilities of the p-type transistors and the n-type transistors are the same, the difference in speed between the rise and fall of the output signal OUT can be reduced.

In the layout of FIG. 17B, the gate contact 161 is placed on the grid line g5, and the gate contact 162 is placed on the grid line g5. In the layout of FIG. 17B, also, since signal supply to the n-type transistors is hastened and signal supply to the p-type transistors is delayed, the fall of the output signal OUT can be hastened. Also, in the layout of FIG. 17B, compared with the layout of FIG. 17A, since signal supply to the p-type transistors is more delayed, the effect is greater.

The gate contact 161 and the gate contact 162 may be placed on different grid lines from each other. For example, it is acceptable to place the gate contact 161 on the grid line g4 and place the gate contact 162 on the grid line g5. In reverse, it is acceptable to place the gate contact 161 on the grid line g5 and place the gate contact 162 on the grid line g4.

In the above case, however, it is preferable to place the gate contact 162 connecting the metal interconnect 152 corresponding to the input node B and the gate interconnect 132 to be farther from the p-type transistor, i.e., closer to the power supply line 12 supplying VSS. The reason is that, since the n-type transistor N2 of which the gate is connected to the input node B is connected at a farther position with respect to the output node OUT, the difference in speed between the rise and fall of the output signal OUT arises more largely for the transition of the input signal B.

Therefore, as in the layout of FIG. 17C, the gate contact 161 may be placed on the grid line g3 and the gate contact 162 on the grid line g4. In this case, also, the effect of hastening the fall of the output signal OUT can be obtained. Note that, in the layout of FIG. 17C, the gate contact 162 may be placed on the grid line g5.

Note that it is also acceptable to place the gate contact 161 on the grid line g4 or g5 and place the gate contact 162 on the grid line g3. In this case, also, the effect of hastening the fall of the output signal OUT can be obtained.

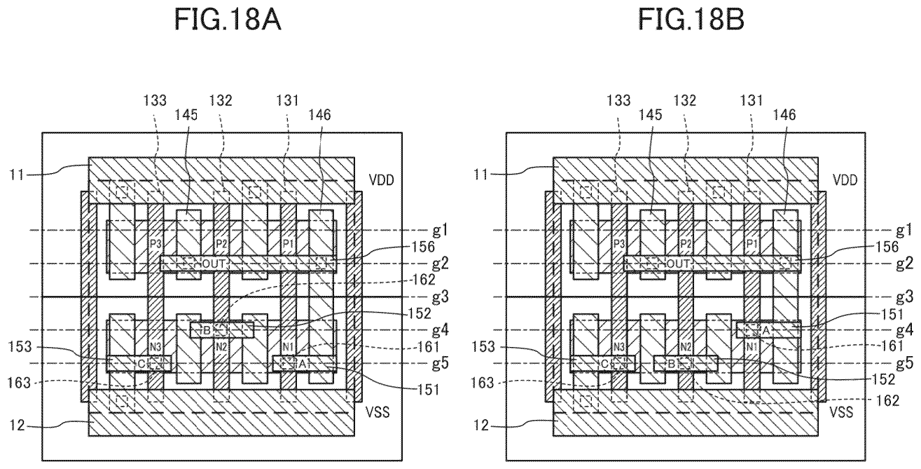

FIGS. 18A-18B are plan views showing layout examples of standard cells implementing 3-input NAND circuits. A gate interconnect 131 corresponds to the gates of the transistors P1 and N1, a gate interconnect 132 corresponds to the gates of the transistors P2 and N2, and a gate interconnect 133 corresponds to the gates of the transistors P3 and N3. A metal interconnect 151 corresponding to the input node A is connected to the gate interconnect 131 through a gate contact 161. A metal interconnect 152 corresponding to the input node B is connected to the gate interconnect 132 through a gate contact 162. A metal interconnect 153 corresponding to the input node C is connected to the gate interconnect 133 through a gate contact 163. A metal interconnect 156 corresponding to the output node OUT is connected to a local interconnect 145 corresponding to the drains of the transistors P2 and P3 and to a local interconnect 146 corresponding to the drains of the transistors P1 and N1 through contacts.

In the layout of FIG. 18A, the gate contact 161 connecting the metal interconnect 151 corresponding to the input node A and the gate interconnect 131 is placed on the grid line g5. Also, the gate contact 162 connecting the metal interconnect 152 corresponding to the input node B and the gate interconnect 132 is placed on the grid line g4. The gate contact 163 connecting the metal interconnect 153 corresponding to the input node C and the gate interconnect 133 is placed on the grid line g5.

In the layout of FIG. 18B, the gate contact 161 is placed on the grid line g4, the gate contact 162 is placed on the grid line g5, and the gate contact 163 is placed on the grid line g5.

That is, since the gate contacts for supplying the input signals A, B, and C are on the n-type transistor part, signal supply to the n-type transistors is hastened and signal supply to the p-type transistors is delayed. With this, the fall of the output signal OUT can be hastened. For example, assuming that the drive capabilities of the p-type transistors and the n-type transistors are the same, the difference in speed between the rise and fall of the output signal OUT can be reduced.

Note that the gate contacts 161, 162, and 163 can be placed on either one, the grid line g4 or g5 In this case, however, it is preferable to place the gate contact 163 connecting the metal interconnect 153 corresponding to the input node C and the gate interconnect 133 on the grid line g5, the one farther from the p-type transistor. The reason is that, since the n-type transistor N3 of which the gate is connected to the input node C is connected at the farthest position with respect to the output node OUT, the difference in speed between the rise and fall of the output signal OUT arises most largely for the transition of the input signal C.

Only some of the gate contacts 161, 162, and 163 may be placed on either the grid line g4 or g5. For example, it is acceptable to place the gate contacts 161 and 162 on the grid line g3 and place the gate contact 163 on the grid line g4 or g5. Otherwise, it is acceptable to place the gate contact 161 on the grid line g3 and place the gate contacts 162 and 163 on the grid line g4 or g5. In any case, it is preferable to place the gate contact 163, among the gate contacts 161, 162, and 163, at a position farthest from the p-type transistor.

### Alteration

A configuration similar to that described in the above embodiment can also be applied to a NOR circuit.

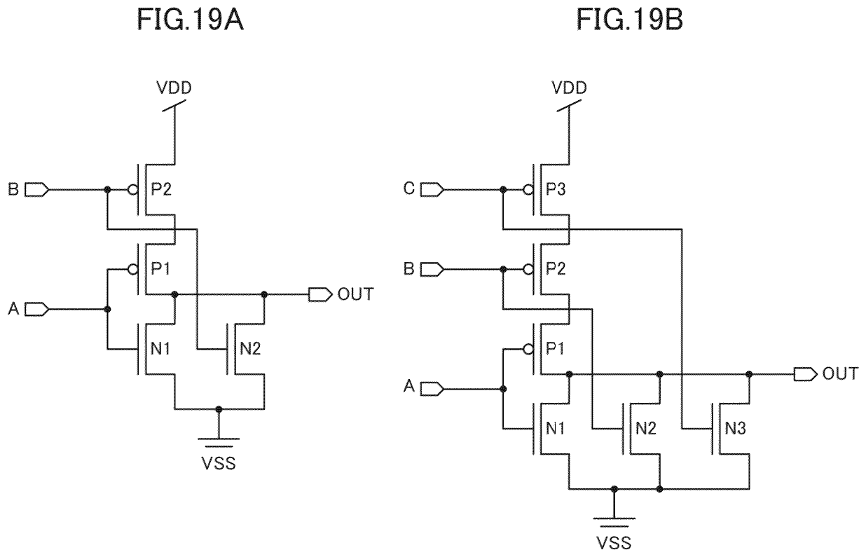

FIGS. 19A-19B are circuit diagrams showing circuit structures of NOR circuits, where FIG. 19A shows a 2-input NOR circuit and FIG. 19B shows a 3-input NOR circuit.

As shown in FIG. 19A, in the 2-input NOR circuit, p-type transistors P1 and P2 are connected in series between an output node OUT and VDD, and n-type transistors N1 and N2 are connected in parallel between VSS and the output node OUT. An input node A is connected to the gates of the p-type transistor P1 and the n-type transistor N1. An input node B is connected to the gates of the p-type transistor P2 and the n-type transistor N2.

As shown in FIG. 19B, in the 3-input NAND circuit, p-type transistors P1, P2, and P3 are connected in series between an output node OUT and VDD, and n-type transistors N1, N2, and N3 are connected in parallel between VSS and the output node OUT. An input node A is connected to the gates of the p-type transistor P1 and the n-type transistor N1. An input node B is connected to the gates of the p-type transistor P2 and the n-type transistor N2. An input node C is connected to the gates of the p-type transistor P3 and the n-type transistor N3.

As shown in FIGS. 19A-19B, in the 2-input NOR circuit and the 3-input NOR circuit, the p-type transistors are connected in series between the output node OUT and VDD. Therefore, assuming that the drive capabilities of the p-type transistors and the n-type transistors are the same, the rise of the output signal OUT will be slower than the fall thereof due to the serial connection of the p-type transistors.

In consideration of the above, in this alteration, in layouts of standard cells implementing the 2-input NOR circuit and the 3-input NOR circuit, gate contacts for supplying input signals to the gates of p-type transistors and n-type transistors are placed on the p-type transistor part. Since this hastens signal supply to the p-type transistors while delaying signal supply to the n-type transistors, the rise of the output signal OUT can be hastened.

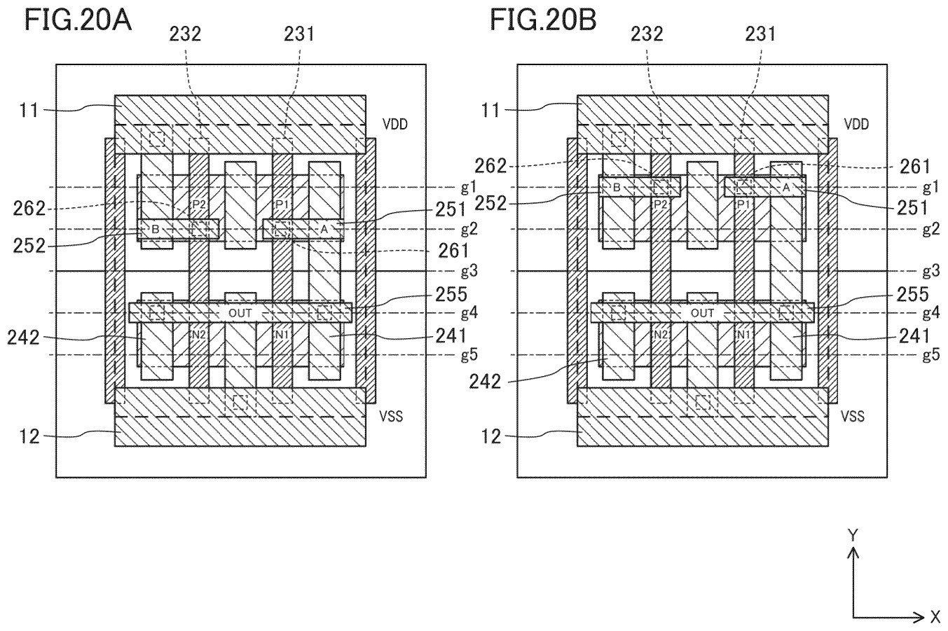

FIGS. 20A-20B are plan views showing layout examples of standard cells implementing 2-input NOR circuits. A gate interconnect 231 corresponds to the gates of the transistors P1 and N1, and a gate interconnect 232 corresponds to the gates of the transistors P2 and N2. A metal interconnect 251 corresponding to the input node A is connected to the gate interconnect 231 through a gate contact 261. A metal interconnect 252 corresponding to the input node B is connected to the gate interconnect 232 through a gate contact 262. A metal interconnect 255 corresponding to the output node OUT is connected to a local interconnect 241 corresponding to the drains of the transistors P1 and N1 and to a local interconnect 242 corresponding to the drain of the transistor N2 through contacts.

In the layout of FIG. 20A, the gate contact 261 connecting the metal interconnect 251 corresponding to the input node A and the gate interconnect 231 is placed on the grid line g2. Also, the gate contact 262 connecting the metal interconnect 252 corresponding to the input node B and the gate interconnect 232 is placed on the grid line g2. That is, since the gate contacts for supplying the input signals A and B are on the p-type transistor part, signal supply to the p-type transistors is hastened and signal supply to the n-type transistors is delayed. With this, the rise of the output signal OUT can be hastened. For example, assuming that the drive capabilities of the p-type transistors and the n-type transistors are the same, the difference in speed between the rise and fall of the output signal OUT can be reduced.

In the layout of FIG. 20B, the gate contact 261 is placed on the grid line g1, and the gate contact 262 is placed on the grid line g1. In the layout of FIG. 20B, also, since signal supply to the p-type transistors is hastened and signal supply to the n-type transistors is delayed, the rise of the output signal OUT can be hastened. Also, in the layout of FIG. 20B, compared with the layout of FIG. 20A, since signal supply to the n-type transistors is more delayed, the effect is greater.

The gate contact 261 and the gate contact 262 may be placed on different grid lines from each other. For example, it is acceptable to place the gate contact 261 on the grid line g2 and place the gate contact 262 on the grid line g1. In reverse, it is acceptable to place the gate contact 261 on the grid line g1 and place the gate contact 262 on the grid line g2.

In the above case, however, it is preferable to place the gate contact 262 connecting the metal interconnect 252 corresponding to the input node B and the gate interconnect 232 at a position farther from the n-type transistor, i.e., closer to the power supply line 11 supplying VDD. The reason is that, since the p-type transistor P2 of which the gate is connected to the input node B is connected at a farther position with respect to the output node OUT, the difference in speed between the rise and fall of the output signal OUT arises largely for the transition of the input signal B.

Therefore, for example, it is acceptable to place the gate contact 261 on the grid line g3 and place the gate contact 262 on the grid line g2 or g1. In this case, also, the effect of hastening the rise of the output signal OUT can be obtained. It is also acceptable to place the gate contact 261 on the grid line g2 or g1 and place the gate contact 262 on the grid line g3.

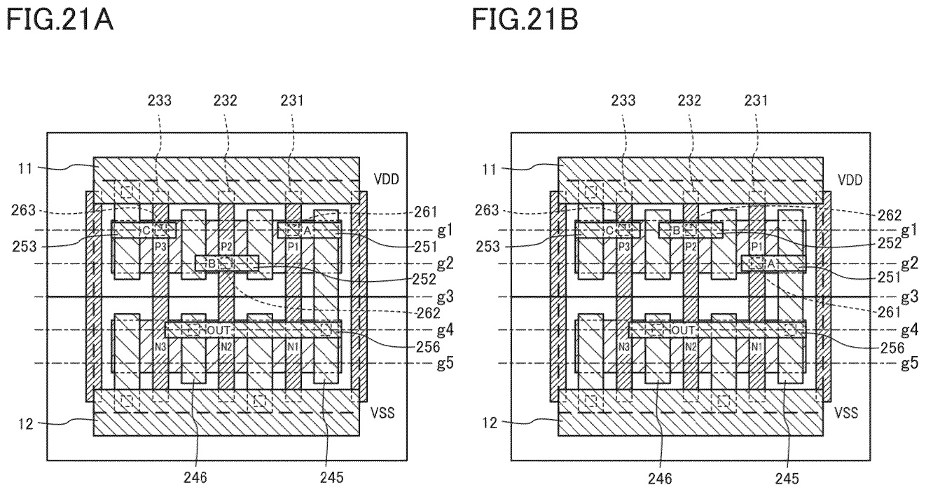

FIGS. 21A-21B are plan views showing layout examples of standard cells implementing 3-input NOR circuits. A gate interconnect 231 corresponds to the gates of the transistors P1 and N1, a gate interconnect 232 corresponds to the gates of the transistors P2 and N2, and a gate interconnect 233 corresponds to the gates of the transistors P3 and N3. A metal interconnect 251 corresponding to the input node A is connected to the gate interconnect 231 through a gate contact 261. A metal interconnect 252 corresponding to the input node B is connected to the gate interconnect 232 through a gate contact 262. A metal interconnect 253 corresponding to the input node C is connected to the gate interconnect 233 through a gate contact 263. A metal interconnect 256 corresponding to the output node OUT is connected to a local interconnect 245 corresponding to the drains of the transistors P1 and N1 and to a local interconnect 246 corresponding to the drains of the transistors N2 and N3 through contacts.

In the layout of FIG. 21A, the gate contact 261 connecting the metal interconnect 251 corresponding to the input node A and the gate interconnect 231 is placed on the grid line g1. Also, the gate contact 262 connecting the metal interconnect 252 corresponding to the input node B and the gate interconnect 232 is placed on the grid line g2. The gate contact 263 connecting the metal interconnect 253 corresponding to the input node C and the gate interconnect 233 is placed on the grid line g1.

In the layout of FIG. 21B, the gate contact 261 is placed on the grid line g2, the gate contact 262 is placed on the grid line g1, and the gate contact 263 is placed on the grid line g1.

That is, since the gate contacts for supplying the input signals A, B, and C are on the p-type transistor part, signal supply to the p-type transistors is hastened, and signal supply to the n-type transistors is delayed. With this, the rise of the output signal OUT can be hastened. For example, assuming that the drive capabilities of the p-type transistors and the n-type transistors are the same, the difference in speed between the rise and fall of the output signal OUT can be reduced.

Note that the gate contacts 261, 262, and 263 can be placed on either one, the grid line g1 or g2 In this case, however, it is preferable to place the gate contact 263 connecting the metal interconnect 253 corresponding to the input node C and the gate interconnect 233 on the grid line g1, the one farther from the n-type transistor. The reason is that, since the p-type transistor P3 of which the gate is connected to the input node C is connected at the farthest position with respect to the output node OUT, the difference in speed between the rise and fall of the output signal OUT arises most largely for the transition of the input signal C.

Only some of the gate contacts 261, 262, and 263 may be placed on either the grid line g1 or g2. In this case, for example, the gate contacts 261 and 262 may be placed on the grid line g3, and the gate contact 263 may be placed on the grid line g1 or g2. Otherwise, the gate contact 261 may be placed on the grid line g3, and the gate contacts 262 and 263 may be placed on the grid line g1 or g2. In any case, it is preferable to place the gate contact 263, among the gate contacts 261, 262, and 263, at a position farthest from the n-type transistor.

Note that the pattern of placement of the grid lines, such as the number of lines and the spacing, in the standard cells are not limited to those shown in the above embodiments.

While the semiconductor integrated circuit device was described as including standard cells having nanosheet FETs, the transistors in the standard cells according to the present disclosure are not limited to nanosheet FETs.

According to the present disclosure, in a semiconductor integrated circuit device, the characteristics of a standard cell can be improved by the style of placement of gate contacts. The present disclosure is therefore useful for improvement of the performance of system LSI, for example.

1. A semiconductor integrated circuit device comprising a standard cell, wherein
the standard cell includes
a first transistor of a first conductivity type and a second transistor of a second conductivity type, their gates being mutually connected and their drains mutually connected,
a third transistor of the first conductivity type and a fourth transistor of the second conductivity type, their gates being mutually connected and their drains mutually connected,
a first metal interconnect corresponding to an input node, connected to the gates of the first and second transistors,
a second metal interconnect corresponding to an intermediate node, connecting the drains of the first and second transistors and the gates of the third and fourth transistors, and
a third metal interconnect corresponding to an output node, connected to the drains of the third and fourth transistors,
the first and third transistors share a source, and the source is connected to a first power supply,
the second and fourth transistors share a source, and the source is connected to a second power supply,
the second metal interconnect is connected to a first gate interconnect corresponding to the gates of the third and fourth transistors through a first gate contact, and
the first gate contact is placed at a position overlapping the third transistor in planar view.

2. The semiconductor integrated circuit device of claim 1, wherein
in the standard cell, the first metal interconnect is connected to a second gate interconnect corresponding to the gates of the first and second transistors through a second gate contact, and
the second gate contact is placed at a position overlapping the first transistor in planar view.

3. The semiconductor integrated circuit device of claim 1, wherein
in the standard cell, the third metal interconnect is connected to a first local interconnect corresponding to the drains of the third and fourth transistors through a first contact, and
the first contact is placed at a position overlapping the third transistor in planar view.

4. The semiconductor integrated circuit device of claim 1, further comprising:
a first power supply line extending in a first direction, supplying first power from the first power supply; and
a second power supply line extending in the first direction, supplying second power from the second power supply,
wherein
the first to fourth transistors are nanosheet transistors having a channel length in the first direction, and
between the first power supply line and the second power supply line, the first and second transistors are placed side by side in a second direction perpendicular to the first direction in an order of the first transistor and the second transistor from the first power supply line side, and the third and fourth transistors are placed side by side in the second direction in an order of the third transistor and the fourth transistor from the first power supply line side at positions adjacent to the first and second transistors in the first direction.

5. The semiconductor integrated circuit device of claim 4, wherein
the first gate contact is placed at a position closer to the first power supply line than a center of a channel region of the third transistor in the second direction in planar view.

6. The semiconductor integrated circuit device of claim 4, wherein
the first gate contact is placed at a position farther from the first power supply line than a center of a channel region of the third transistor in the second direction in planar view.

7. The semiconductor integrated circuit device of claim 2, further comprising:
a first power supply line extending in a first direction, supplying first power from the first power supply; and
a second power supply line extending in the first direction, supplying second power from the second power supply,
wherein the first to fourth transistors are nanosheet transistors having a channel length in the first direction, and
between the first power supply line and the second power supply line, the first and second transistors are placed side by side in a second direction perpendicular to the first direction in an order of the first transistor and the second transistor from the first power supply line side, and the third and fourth transistors are placed side by side in the second direction in an order of the third transistor and the fourth transistor from the first power supply line side at positions adjacent to the first and second transistors in the first direction.

8. The semiconductor integrated circuit device of claim 7, wherein
the second gate contact is placed at a position closer to the first power supply line than a center of a channel region of the first transistor in the second direction in planar view.

9. The semiconductor integrated circuit device of claim 7, wherein
the second gate contact is placed at a position farther from the first power supply line than a center of a channel region of the first transistor in the second direction in planar view.

10. A semiconductor integrated circuit device comprising a standard cell, wherein
the standard cell includes
a first transistor of a first conductivity type and a second transistor of a second conductivity type, their gates being mutually connected and their drains mutually connected,
a third transistor of the first conductivity type and a fourth transistor of the second conductivity type, their gates being mutually connected and their drains mutually connected,
a first metal interconnect corresponding to an input node, connected to the gates of the first and second transistors,
a second metal interconnect corresponding to an intermediate node, connecting the drains of the first and second transistors and the gates of the third and fourth transistors, and
a third metal interconnect corresponding to an output node, connected to the drains of the third and fourth transistors,
the first and third transistors share a source, and the source is connected to a first power supply,
the second and fourth transistors share a source, and the source is connected to a second power supply,
the first metal interconnect is connected to a first gate interconnect corresponding to the gates of the first and second transistors through a first gate contact,
the first gate contact is placed at a position overlapping the first transistor in planar view,
the second metal interconnect is connected to a second gate interconnect corresponding to the gates of the third and fourth transistors through a second gate contact, and
the second gate contact is placed at a position overlapping the fourth transistor in planar view.

11. The semiconductor integrated circuit device of claim 10, wherein
in the standard cell, the third metal interconnect is connected to a first local interconnect corresponding to the drains of the third and fourth transistors through a first contact, and
the first contact is placed at a position overlapping the fourth transistor in planar view.

12. The semiconductor integrated circuit device of claim 10, further comprising:
a first power supply line extending in a first direction, supplying first power from the first power supply; and
a second power supply line extending in the first direction, supplying second power from the second power supply,
wherein
the first to fourth transistors are nanosheet transistors having a channel length in the first direction, and
between the first power supply line and the second power supply line, the first and second transistors are placed side by side in a second direction perpendicular to the first direction in an order of the first transistor and the second transistor from the first power supply line side, and the third and fourth transistors are placed side by side in the second direction in an order of the third transistor and the fourth transistor from the first power supply line side at positions adjacent to the first and second transistors in the first direction.

13. The semiconductor integrated circuit device of claim 12, wherein
the first gate contact is placed at a position closer to the first power supply line than a center of a channel region of the first transistor in the second direction in planar view.

14. The semiconductor integrated circuit device of claim 12, wherein
the first gate contact is placed at a position farther from the first power supply line than a center of a channel region of the first transistor in the second direction in planar view.

15. The semiconductor integrated circuit device of claim 12, wherein
the second gate contact is placed at a position closer to the second power supply line than a center of a channel region of the fourth transistor in the second direction in planar view.

16. The semiconductor integrated circuit device of claim 12, wherein
the second gate contact is placed at a position farther from the second power supply line than a center of a channel region of the fourth transistor in the second direction in planar view.

17. A semiconductor integrated circuit device comprising a standard cell, wherein
the standard cell includes
first and second transistors of a first conductivity type connected in parallel between a first power supply and an output node,
third and fourth transistors of a second conductivity type connected in series between the output node and a second power supply,
a first metal interconnect corresponding to a first input node, connected to gates of the first and third transistors,
a second metal interconnect corresponding to a second input node, connected to gates of the second and fourth transistors, and
a third metal interconnect corresponding to the output node, connected to drains of the first, second, and third transistors,
the first metal interconnect is connected to a first gate interconnect corresponding to the gates of the first and third transistors through a first gate contact,
the second metal interconnect is connected to a second gate interconnect corresponding to the gates of the second and fourth transistors through a second gate contact, and
at least one of the first and second gate contacts is placed at a position overlapping the third or fourth transistor in planar view.

18. The semiconductor integrated circuit device of claim 17, wherein
the second gate contact is placed at a position farther from the third metal interconnect than the first gate contact.

19. A semiconductor integrated circuit device comprising a standard cell, wherein
the standard cell includes
first, second, and third transistors of a first conductivity type connected in parallel between a first power supply and an output node,
fourth, fifth, and sixth transistors of a second conductivity type connected in series between the output node and a second power supply,
a first metal interconnect corresponding to a first input node, connected to gates of the first and fourth transistors,
a second metal interconnect corresponding to a second input node, connected to gates of the second and fifth transistors,
a third metal interconnect corresponding to a third input node, connected to gates of the third and sixth transistors, and
a fourth metal interconnect corresponding to the output node, connected to drains of the first, second, third, and fourth transistors,
the first metal interconnect is connected to a first gate interconnect corresponding to the gates of the first and fourth transistors through a first gate contact,
the second metal interconnect is connected to a second gate interconnect corresponding to the gates of the second and fifth transistors through a second gate contact,
the third metal interconnect is connected to a third gate interconnect corresponding to the gates of the third and sixth transistors through a third gate contact, and
at least one of the first, second, and third gate contacts is placed at a position overlapping the fourth, fifth, or sixth transistor in planar view.

20. The semiconductor integrated circuit device of claim 19, wherein
the third gate contact, among the first to third gate contacts, is placed at a position farthest from the fourth metal interconnect.
